(19) United States
(12) Patent Application Publication
(10) Pub. No.: US 2011/0150036 A1
(43) Pub. Date: Jun. 23, 2011

(54) FLEXIBLE THERMOELECTRIC GENERATOR, WIRELESS SENSOR NODE INCLUDING THE SAME AND METHOD OF MANUFACTURING THE SAME

(75) Inventors: Jae Woo Lee, Daejeon (KR); Yil Suk Yang, Daejeon (KR); Se Wan Heo, Daejeon (KR); Moon Gyu Jang, Daejeon (KR); Jong Dae Kim, Daejeon (KR)

(73) Assignee: ELECTRONICS AND TELECOMMUNICATIONS RESEARCH INSTITUTE, Daejeon (KR)

(21) Appl. No.: 12/949,479

(22) Filed: Nov. 18, 2010

(30) Foreign Application Priority Data
Dec. 21, 2009 (KR) 10-2009-0128361
Mar. 19, 2010 (KR) 10-2010-0024621

(51) Int. Cl. G01K 7/02; H01L 35/32; H01L 21/30

(52) U.S. Cl. 374/179; 136/211; 438/54; 257/E21.211; 374/E07.004

(57) ABSTRACT

Provided are a flexible thermoelectric generator, a wireless sensor node including the same and a method of manufacturing the same. The flexible thermoelectric generator includes a plurality of P-type semiconductors and a plurality of N-type semiconductors, which are alternately arranged, an upper metal for connecting upper surfaces of the adjacent P-type semiconductor and N-type semiconductor, a lower metal for connecting lower surfaces of the adjacent P-type semiconductor and N-type semiconductor, and alternately disposed with respect to the upper metal, a P-type metal connected to at least one P-type semiconductor among the plurality of P-type semiconductors, and an N-type metal connected to at least one N-type semiconductor among the plurality of N-type semiconductors.

### CROSS-REFERENCE TO RELATED APPLICATION

This application claims priority to and the benefit of Korean Patent Application No. 10-2009-0128361 filed Dec. 21, 2009, and 10-2010-0024621 filed Mar. 19, 2010, the disclosure of which is incorporated herein by reference in its entirety.

### BACKGROUND

The present invention relates to a flexible thermoelectric generator, a wireless sensor node including the same and a method of manufacturing the same. More specifically, the present invention relates to a flexible thermoelectric generator, a wireless sensor node including the same and a method of manufacturing the same that are capable of supplying energy generated by a change in temperature instead of a conventional battery and substituting for a conventional temperature sensor using characteristics of a change in output voltage according to the change in temperature.

### Discussion of Related Art

In recent times, as portable electronic devices and mobile terminals become more widely used, research and development on mobile electric generator fields are being actively performed. A thermoelectric generator is known as a type of energy harvesters. The thermoelectric generator generally includes three parts: a heat source, a heat sink, and a thermopile. Here, the thermopile is constituted by a plurality of thermocouples connected in series, and used to convert some heat energy into electric energy. That is, the thermoelectric generator generates electric power based on a heat gradient crossing the thermocouples of the thermopile. Specifically, the thermoelectric generator receives heat energy through a “hot” side surface or a junction, and passes the heat energy through the thermopile to discharge the heat energy through a “cold” side surface or a junction, converting the heat energy into electric power.

In general, the thermoelectric generators are formed of semiconductor materials. The semiconductor materials are electrically connected in series and thermally connected in parallel to form a thermocouple, forming two junctions. The semiconductor materials are typically classified into N-types and P-types. In a typical thermoelectric device, an electrical conductive connection is formed between P-type and N-type semiconductor materials, and carriers move from a hot junction to a cold junction to induce a current through heat diffusion.

FIG. 1 is a cross-sectional view showing a structure of a conventional thermoelectric generator.

Referring to FIG. 1, a conventional thermoelectric generator 100 includes a heating plate 110, a heat transfer medium 120, a P-type semiconductor 130, a P-type metal 132, an N-type semiconductor 140, an N-type metal 142, a metal 150, a cold transfer medium 160, and a cooling plate 170.

The P-type semiconductor 130 and the N-type semiconductor 140 are disposed parallel to each other, and electrically connected by the metal 150 in series to transfer heat energy supplied from the heating plate 110 to the cooling plate 170. At this time, current generates between the P-type semiconductor 130 and the N-type semiconductor 140. Thus, the current flows to the exterior through the P-type metal 132 and the N-type metal 142. According to the above theory, the thermoelectric generator 100 converts the heat energy into the electric energy.

However, the existing thermoelectric generator has a limited efficiency and electric potential when it is formed in a relatively small size. Since a conventional semiconductor deposition technique is used to manufacture the thermoelectric generator, the thermoelectric generators formed through difficult synthesis processes are subjected to numerous restrictions in process, which lead to disadvantages in size and performance.

For example, the currently applicable thermoelectric generators have a structure similar to that of FIG. 1, and thus, each thermoelectric generator typically has a length and width in the order of several millimeters. These thermoelectric generators cannot provide voltages satisfying input requirements of numerous devices including power control electrons.

Meanwhile, a wireless sensor node needs a thermoelectric generator that uses a temperature gradient of about 10° C. or less as well as a thermoelectric generator operating at room temperature or thereabout. For example, sensors used for climate control or military purposes are operated at a temperature difference of 5 to 20° C. when ambient energy is used.

In addition, the thermoelectric generator is very advantageous in operation of a specific device that requires an electric energy source of an interconnection or battery-power at a remote or non-access area. For example, remote sensors can be easily disposed to obtain data for measuring temperature, pressure, humidity, presence and movement of a transportation vehicle, a human or an animal, or other environmental characteristics. However, the wireless sensor node energized by a battery has a disadvantage in power due to a limited lifespan of the battery. Therefore, remote apparatus exclusively dependent on the batteries are essentially restricted by the lifespan and reliability of the batteries.

In addition, the wireless sensor node is subjected to another restriction. For example, a plurality of sensors installed at a large building can be usefully applied to provide smart sensing and control of energy transmission and distribution as well as sensing and report of environmental conditions. However, since the conventional power solution is inappropriate or too expensive, it is impossible to realize this solution. That is, power feed to all sensors by batteries requires much cost due to initial installation and periodical movement, and causes performance restriction of the batteries. In order to solve the problem, a method of interconnecting the plurality of sensors through one central power supply may be proposed. However, this method is also impractical due to a complex circuit and excessive cost.

### SUMMARY OF THE INVENTION

The present invention is directed to a self-driven wireless sensor node operated by an energy storage device in which energy is charged according to variation in temperature, with no battery used in a conventional wireless sensor node for sensing variation in temperature.

The present invention is also directed to a wireless sensor node capable of detecting variation in external temperature using an output value of a thermoelectric generator instead of a temperature sensor, and transmitting the variation in a wireless manner.

One aspect of the present invention provides a flexible thermoelectric generator including: a plurality of P-type semiconductors and a plurality of N-type semiconductors, which are alternately arranged; an upper metal for connecting upper surfaces of the adjacent P-type semiconductor and N-type semiconductor; a lower metal for connecting lower surfaces of the adjacent P-type semiconductor and N-type semiconductor, and alternately disposed with respect to the upper metal; a P-type metal connected to at least one P-type semiconductor among the plurality of P-type semiconductors; and an N-type metal connected to at least one N-type semiconductor among the plurality of N-type semiconductors.

Another aspect of the present invention provides a method of manufacturing a flexible thermoelectric generator, which includes: forming a plurality of P-type semiconductors and a plurality of N-type semiconductors, which are alternately arranged, in a substrate; forming a metal layer on an upper surface of the substrate; patterning the metal layer to form an upper metal for connecting upper surfaces of the adjacent P-type semiconductor and N-type semiconductor, a P-type metal connected to at least one P-type semiconductor among the plurality of P-type semiconductors, and an N-type metal connected to at least one N-type semiconductor among the plurality of N-type semiconductors; etching a lower surface of the substrate to expose lower surfaces of the plurality of P-type semiconductors and the plurality of N-type semiconductors; forming a metal layer on the lower surface of the substrate to which the lower surfaces of the plurality of P-type semiconductors and the plurality of N-type semiconductors are exposed; and patterning the metal layer to connect the lower surfaces of the adjacent P-type semiconductor and N-type semiconductor, and forming a lower metal alternately disposed with respect to the upper metal.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a cross-sectional view showing a structure of a conventional thermoelectric generator;

FIG. 2 is a cross-sectional view showing a structure of a flexible thermoelectric generator in accordance with an exemplary embodiment of the present invention;

FIGS. 3A to 3E are cross-sectional views for explaining a method of manufacturing a flexible thermoelectric generator in accordance with another exemplary embodiment of the present invention;

FIG. 4 is a view showing a configuration of the thermoelectric generator to which a heating plate and a cooling plate are attached;

FIG. 5 is a view showing an array in which flexible thermoelectric generators in accordance with an exemplary embodiment of the present invention are connected in series;

FIG. 6 is a view showing a configuration of a wireless sensor node in accordance with still another exemplary embodiment of the present invention;

FIG. 7 is a block diagram showing the entire configuration of the wireless sensor node in accordance with the present invention; and

FIG. 8 is a block diagram showing a configuration of a wireless sensor node and a sink node as a base station in accordance with an exemplary embodiment of the present invention.

### DETAILED DESCRIPTION OF EMBODIMENTS

The present invention will be described more fully hereinafter with reference to the accompanying drawings, in which exemplary embodiments of the invention are shown. This invention may, however, be embodied in different forms and should not be construed as limited to the embodiments set forth herein.

While the embodiment in accordance with the present invention illustrates two pairs of P-type semiconductors and N-type semiconductors for the convenience of description, the present invention is not limited thereto and the flexible thermoelectric generator in accordance with the present invention may include a plurality of pairs of P-type semiconductors and N-type semiconductors. In addition, the flexible thermoelectric generator may be variously connected in series or in parallel.

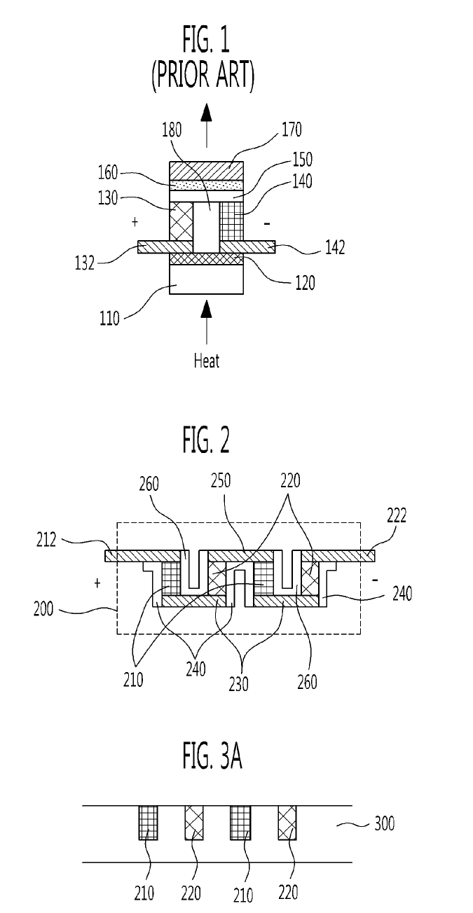

FIG. 2 is a cross-sectional view showing a structure of a flexible thermoelectric generator in accordance with an exemplary embodiment of the present invention.

Referring to FIG. 2, a flexible thermoelectric generator 200 in accordance with the present invention may include a plurality of P-type semiconductors 210 and a plurality of N-type semiconductors 220, which are alternately arranged, an upper metal 250 for connecting upper surfaces of the adjacent P-type semiconductor 210 and N-type semiconductor 220, a lower metal 230 for connecting lower surfaces of the adjacent P-type semiconductor 210 and N-type semiconductor 220 and alternately disposed with respect to the upper metal 250, a P-type metal 212 connected to at least one P-type semiconductor 210 among the plurality of P-type semiconductors 210, and an N-type metal 222 connected to at least one N-type semiconductor 220 among the plurality of N-type semiconductors 220. The flexible thermoelectric generator 200 may further include protective layers 240 and 260 formed along a connection surface of the plurality of P-type semiconductors 210, the plurality of N-type semiconductors 220, the upper metal 250 and the lower metal 230.

The plurality of P-type semiconductors 210 and the plurality of N-type semiconductors 220 are alternately disposed parallel to each other and electrically connected in series by the lower and upper metals 230 and 250. Therefore, the plurality of P-type semiconductors 210 and the plurality of N-type semiconductors 220 are thermally disposed in parallel and electrically connected in series.

According to the above structure, the plurality of P-type semiconductors 210 and the plurality of N-type semiconductors 220 transfer heat, and at this time, current is generated between the plurality of P-type semiconductors 210 and the plurality of N-type semiconductors 220.

The P-type metal 212 and the N-type metal 222 are connected to one ends of one P-type semiconductor among the plurality of P-type semiconductors 210 and one N-type semiconductor among the plurality of N-type semiconductors 220, respectively, so that current can flow to the exterior.

The lower metal 230 connects lower surfaces of the plurality of P-type semiconductors 210 and lower surfaces of the plurality of N-type semiconductors 220 to electrically connect the plurality of P-type semiconductors 210 and the plurality of N-type semiconductors 220.

The upper metal 250 connects upper surfaces of the plurality of P-type semiconductors 210 and upper surfaces of the plurality of N-type semiconductors 220 to electrically connect the plurality of P-type semiconductors 210 and the plurality of N-type semiconductors 220.

The protective layers 240 and 260 include a plurality of upper protective layers 260 and a plurality of lower protective layers 240. The lower protective layer 240 is attached to a lower recess of a structure constituted by the plurality of P-type semiconductors 210, the P-type metal 212, the plurality of N-type semiconductors 220, the N-type metal 222, the lower metal 230 and the upper metal 250, providing flexibility to the flexible thermoelectric generator 200. The upper protective layer 260 is attached to an upper recess of the structure to provide flexibility to the flexible thermoelectric generator 200. For this, the lower protective layer 240 and the upper protective layer 260 may be formed of an elastic material, for example, a metal, plastic or rubber material.

Therefore, the flexible thermoelectric generator 200 in accordance with the present invention maintains a general coil shape and may have flexibility.

As described above, the flexible thermoelectric generator 200 in accordance with the present invention may further include the lower protective layer 240 and the upper protective layer 260 in addition to the conventional thermoelectric generator, securing flexibility.

That is, as shown in FIG. 1 of the conventional art, an air space 180 is provided between the P-type semiconductor 130 and the N-type semiconductor 140. On the other hand, in the present invention, the thermoelectric generator may include the lower protective layer 240 and the upper protective layer 260 to have flexibility and a circular shape when the thermoelectric generator is arranged in an in-line array. Due to these characteristics, the flexible thermoelectric generator 200 in accordance with the present invention has good compatibility to be easily applied to various sensor nodes.

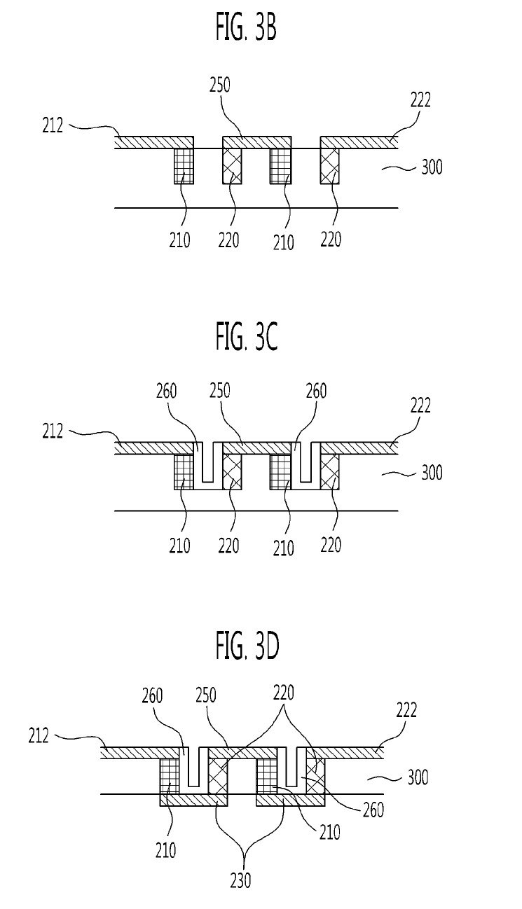

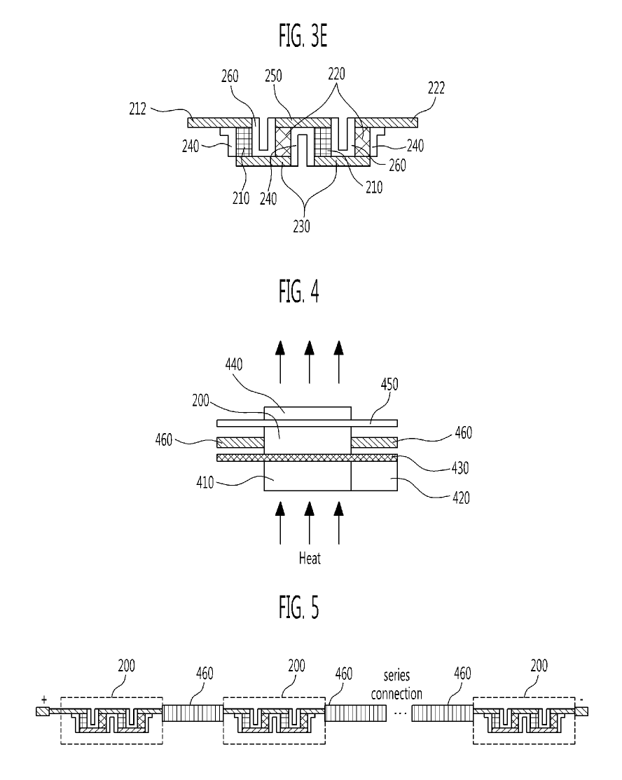

FIGS. 3A to 3E are cross-sectional views for explaining a method of manufacturing a flexible thermoelectric generator in accordance with another exemplary embodiment of the present invention.

Referring to FIG. 3A, a plurality of P-type semiconductors 210 and a plurality of N-type semiconductors 220, which are alternately arranged, are formed in a substrate 300. At this time, the plurality of P-type semiconductors 210 and the plurality of N-type semiconductors 220 may be formed through an ion implantation process, a diffusion process, or the like.

Referring to FIG. 3B, after forming a metal layer on an upper surface of the substrate 300, the formed metal layer is patterned to form an upper metal 250 to electrically connect the P-type semiconductor 210 and the N-type semiconductor 220. At this time, in order to flow current to the exterior of the flexible thermoelectric generator 200, a P-type metal 212 connected to one end of at least one P-type semiconductor 210 among the plurality of P-type semiconductors 210 and an N-type metal 222 connected to one end of at least one N-type semiconductor 220 among the plurality of N-type semiconductors 220 may be simultaneously formed.

Referring to FIG. 3C, the substrate 300 exposed between the upper metal 250, the P-type metal 212 and the N-type metal 222 is etched to a predetermined depth using the upper metal 250, the P-type metal 212 and the N-type metal 222 as an etching barrier. At this time, the substrate 300 between the plurality of P-type semiconductors 210 and the plurality of N-type semiconductors 220 formed in the substrate 300 is removed. Next, an upper protective layer 260 is formed along the etched surface. Here, the upper protective layer 260 formed of an elastic material is formed on an upper recess of a structure constituted by the plurality of P-type semiconductors 210, the P-type metal 212, the plurality of N-type semiconductors 220, the N-type metal 222, the lower metal 230, and the upper metal 250.

Referring to FIG. 3D, to support an intermediate material during the following etching process, an auxiliary substrate (not shown) is adhered to the upper surface of the substrate 300, and then, a lower part of the substrate 300 is removed to a depth at which the plurality of P-type semiconductors 210 and the plurality of N-type semiconductors 220 exist. That is, the lower surface of the substrate 300 is etched to expose lower surfaces of the plurality of P-type semiconductors 210 and the plurality of N-type semiconductors 220. Next, after forming a metal layer on the lower surface of the substrate 300, the formed metal layer is patterned to form the lower metal 230 to electrically connect the plurality of P-type semiconductors 210 and the plurality of N-type semiconductors 220. Here, the lower metal 230 connects the adjacent P-type semiconductor 210 and N-type semiconductor 220, and is alternately arranged with respect to the upper metal 250.

Referring to FIG. 3E, after etching the substrate between the plurality of P-type semiconductors 210 and the plurality of N-type semiconductors 220 using the lower metal 230 as an etching barrier, a lower protective layer 240 is formed along the etched surface. That is, the lower protective layer 240 formed of an elastic material is formed on a lower recess of a structure constituted by the plurality of P-type semiconductors 210, the P-type metal 212, the plurality of N-type semiconductors 220, the N-type metal 222, the lower metal 230, and the upper metal 250.

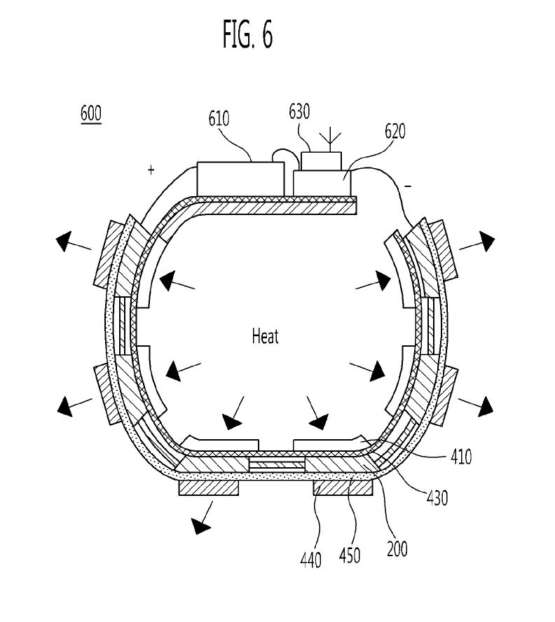

FIG. 4 is a view showing a configuration of the thermoelectric generator to which a heating plate and a cooling plate are attached.

Referring to FIG. 4, a thermal insulating layer 420 is attached to one surface of a heating plate 410 to maintain thermal insulation between thermoelectric generators, and a heat transfer medium 430 is inserted to transfer heat between the flexible thermoelectric generator 200 and the heating plate 410 and securely fix the flexible thermoelectric generator 200 and the heating plate 410. In addition, a cooling transfer media 450 is inserted between the flexible thermoelectric generator 200 and a cooling plate 440 to transfer heat. Therefore, the heating plate 410 or the cooling plate 440 may be heated or cooled through other heat transfer methods, for example, conduction, convection and radiation. As described above, these thermoelectric generators can generate several milliwatts (mw) of electric power from a small difference in temperature (for example, about 3 to 10° C.).

In addition, device connection parts 460 are installed at both walls of the flexible thermoelectric generator 200. Therefore, a plurality of flexible thermoelectric generators 200 may be connected by the device connection parts 460. That is, the plurality of flexible thermoelectric generators may be electrically and flexibly connected to each other.

FIG. 5 is a view showing an array in which flexible thermoelectric generators in accordance with an exemplary embodiment of the present invention are connected in series.

Referring to FIG. 5, in one embodiment of the present invention, device connection parts 460 are used to electrically connect energy generated from the plurality of flexible thermoelectric generators 200. Therefore, the plurality of flexible thermoelectric generators 200 may be manufactured in an arbitrary shape using the device connection parts 460 and applied to various application fields.

FIG. 6 is a view showing a configuration of a wireless sensor node in accordance with still another exemplary embodiment of the present invention.

Referring to FIG. 6, a wireless sensor node 600 in accordance with the present invention includes a flexible thermoelectric generator 200, an energy conversion and storage unit 610, a signal processing unit 620, and a wireless transmission/reception unit 630.

The flexible thermoelectric generator 200 converts heat energy into electrical energy to store the electrical energy into the energy conversion and storage unit 610, and provides an output voltage to the signal processing unit 620.

The energy conversion and storage unit 610 stores the electrical energy generated from the flexible thermoelectric generator 200 and supplies power to the respective devices in the wireless sensor node 600, i.e., the signal processing unit 620 and the wireless transmission/reception unit 630. Here, the energy conversion and storage unit 610 may be constituted by a capacitor, a supercapacitor and a combination thereof.

Therefore, the flexible thermoelectric generator 200 in accordance with the present invention provides electrical energy generated therefrom to the respective devices in the wireless sensor node 600 so that the wireless sensor node 600 can act as a self-driven wireless sensor node, without necessity of a separate battery.

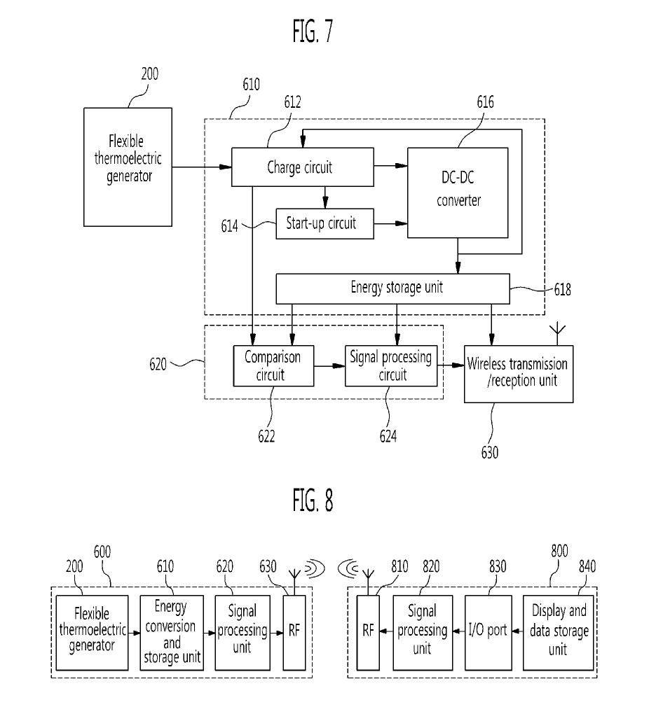

FIG. 7 is a block diagram showing the entire configuration of the wireless sensor node in accordance with the present invention.

Referring to FIG. 7, the energy conversion and storage unit 610 in accordance with the present invention includes a charge circuit 612, a start-up circuit 614, a DC-DC converter 616 and an energy storage unit 618, and the signal processing unit 620 includes a comparison circuit 622 and a signal processing circuit 624.

The charge circuit 612 converts an output voltage of the thermoelectric generator 200 into a desired voltage using the DC-DC converter 616.

The start-up circuit 614 provides a voltage required for an operation of the DC-DC converter 616 upon a start-up of the wireless sensor node 600 to the DC-DC converter 616 using the output voltage of the thermoelectric generator 200. That is, the start-up circuit 614 provides a voltage such that the DC-DC converter 616 can be operated even at a critical voltage (for example, 300 mV) or less.

The energy storage unit 618 stores a voltage made by the charge circuit 612, and supplies the voltage to the respective devices of the wireless sensor node 600, i.e., the comparison circuit 622, the signal processing circuit 624 and the wireless transmission/reception unit 630.

The comparison circuit 622 compares the output voltage of the flexible thermoelectric generator 200 with a reference voltage, and transmits the compared result to the signal processing circuit 624.

The signal processing circuit 624 analyzes the compared result of the comparison circuit 622 to sense variation in temperature, i.e., a temperature signal, and transmits the sensed temperature signal to a base station through the wireless transmission/reception unit 630.

FIG. 8 is a block diagram showing a configuration of a wireless sensor node and a sink node as a base station in accordance with an exemplary embodiment of the present invention.

Referring to FIG. 8, a sink node 800 detects a temperature signal received from a wireless sensor node 600 using a wireless transmission/reception unit 810, and transmits the temperature signal to a display and data storage unit 840 via a signal processing unit 820 and an input/output (I/O) port 830, ultimately processing the temperature signal received from the wireless sensor node 600.

According to the present invention, a self-driven wireless sensor node constituted by a flexible thermoelectric generator is provided so that energy required for the wireless sensor node can be supplied through a self-chargeable method to provide a semi-permanent wireless sensor node. In addition, variation in temperature is sensed by an output voltage of a flexible thermoelectric generator to remove necessity of a separate temperature sensor, providing a simple structure of wireless sensor node.

In the drawings and specification, there have been disclosed typical exemplary embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A flexible thermoelectric generator comprising:
a plurality of P-type semiconductors and a plurality of N-type semiconductors, which are alternately arranged;
an upper metal for connecting upper surfaces of the adjacent P-type semiconductor and N-type semiconductor;
a lower metal for connecting lower surfaces of the adjacent P-type semiconductor and N-type semiconductor, and alternately disposed with respect to the upper metal;
a P-type metal connected to at least one P-type semiconductor among the plurality of P-type semiconductors; and
an N-type metal connected to at least one N-type semiconductor among the plurality of N-type semiconductors.

2. The flexible thermoelectric generator according to claim 1, further comprising a protective layer formed along a connection surface of the plurality of P-type semiconductors, the plurality of N-type semiconductors, the upper metal and the lower metal.

3. The flexible thermoelectric generator according to claim 1, wherein the plurality of P-type semiconductors and the plurality of N-type semiconductors are connected in series.

4. The flexible thermoelectric generator according to claim 2, wherein the protective layer is formed of an elastic material.

5. A wireless sensor node comprising:
a plurality of flexible thermoelectric generators connected by device connection parts;
an energy conversion unit for converting energy generated by the plurality of flexible thermoelectric generators;
a storage unit for storing the energy converted by the energy conversion unit; and
a signal processing unit for receiving power from the storage unit to process a sensed signal.

6. The wireless sensor node according to claim 5, wherein the flexible thermoelectric generator comprises:
a plurality of P-type semiconductors and a plurality of N-type semiconductors, which are alternately arranged;
an upper metal for connecting upper surfaces of the adjacent P-type semiconductor and N-type semiconductor;
a lower metal for connecting lower surfaces of the adjacent P-type semiconductor and N-type semiconductor, and alternately disposed with respect to the upper metal;
a P-type metal connected to at least one P-type semiconductor among the plurality of P-type semiconductors;
an N-type metal connected to at least one N-type semiconductor among the plurality of N-type semiconductors; and
a protective layer formed along a connection surface of the plurality of P-type semiconductors, the plurality of N-type semiconductors, the upper metal and the lower metal.

7. The wireless sensor node according to claim 5, further comprising a wireless transmission/reception unit for receiving power from the storage part and transmitting/receiving a signal processed by the signal processing unit in a wireless manner.

8. The wireless sensor node according to claim 5, further comprising a start-up circuit for enabling energy conversion at a voltage of 300 mV or less.

9. The wireless sensor node according to claim 5, wherein the signal processing unit compares and determines variation in temperature using an output voltage of the flexible thermoelectric generator to process the sensed signal.

10. A method of manufacturing a flexible thermoelectric generator, comprising:
forming a plurality of P-type semiconductors and a plurality of N-type semiconductors, which are alternately arranged, in a substrate;
forming a metal layer on an upper surface of the substrate;
patterning the metal layer to form an upper metal for connecting upper surfaces of the adjacent P-type semiconductor and N-type semiconductor, a P-type metal connected to at least one P-type semiconductor among the plurality of P-type semiconductors, and an N-type metal connected to at least one N-type semiconductor among the plurality of N-type semiconductors;
etching a lower surface of the substrate to expose lower surfaces of the plurality of P-type semiconductors and the plurality of N-type semiconductors;
forming a metal layer on the lower surface of the substrate to which the lower surfaces of the plurality of P-type semiconductors and the plurality of N-type semiconductors are exposed; and
patterning the metal layer to connect the lower surfaces of the adjacent P-type semiconductor and N-type semiconductor, and forming a lower metal alternately disposed with respect to the upper metal.

11. The method according to claim 10, further comprising:
after forming the upper metal, the P-type metal and the N-type metal,
etching the substrate exposed between the upper metal, the P-type metal and the N-type metal to a predetermined depth using the upper metal, the P-type metal and the N-type metal as an etching barrier; and
forming an upper protective layer along the etched surface.

12. The method according to claim 10, further comprising:
after forming the lower metal,
etching the substrate exposed between the lower metals using the lower metal as an etching barrier; and
forming a lower protective layer along the etched surface.

13. The method according to claim 12, further comprising:
forming an auxiliary substrate on the upper surface of the substrate to support a resultant material formed on the lower metal while etching the substrate exposed between the lower metals; and
after forming the lower protective layer, removing the auxiliary substrate.

14. The method according to claim 10, wherein forming the plurality of P-type semiconductors and the plurality of N-type semiconductors is performed by an ion implantation process or a diffusion process.
